(19) United States
(12) Patent Application Publication
(10) Pub. No.: US 2025/0210515 A1
(43) Pub. Date: Jun. 26, 2025

(54) SEMICONDUCTOR DEVICE

(71) Applicant: Renesas Electronics Corporation, Tokyo (JP)

(72) Inventors: Yasutaka NAKASHIBA, Tokyo (JP); Fumitoshi TAKAHASHI, Tokyo (JP); Hiroshi YANAGIGAWA, Tokyo (JP)

(21) Appl. No.: 18/937,186

(22) Filed: Nov. 5, 2024

(30) Foreign Application Priority Data
Dec. 26, 2023 (JP) 2023-218847

(51) Int. Cl. H01L 23/522; H01L 23/00

(52) U.S. Cl. CPC H01L 23/5228; H01L 23/5226; H01L 24/08; H01L 2224/04042; H01L 2224/05025; H01L 2924/30101

(57) ABSTRACT

According to one embodiment, a semiconductor device includes: a semiconductor substrate having an upper surface and a lower surface; a first conductive layer formed above the semiconductor substrate; and a second conductive layer formed on the upper surface of the first conductive layer, in which, when viewed from above, the second conductive layer is formed in a region inside an end edge of the first conductive layer, the thickness of the second conductive layer is larger than the thickness of the first conductive layer, the thermal conductivity of the second conductive layer is larger than the thermal conductivity of the first conductive layer, and the resistivity of the second conductive layer is smaller than the resistivity of the first conductive layer.

### CROSS-REFERENCE TO RELATED APPLICATIONS

The disclosure of Japanese Patent Application No. 2023-218847 filed on Dec. 26, 2023 including the specification, drawings and abstract is incorporated herein by reference in its entirety.

### BACKGROUND

The present disclosure relates to a semiconductor device. There are disclosed techniques listed below.

[Patent Document 1] Japanese Unexamined Patent Application Publication No. 2020-120133

Patent Document 1 discloses a semiconductor device having a conductive layer used for a pad on a semiconductor substrate.

### SUMMARY

When a large current flows through the semiconductor device via the pad, the semiconductor device may generate heat.

Other problems and novel features would become apparent from the description of the present specification and the accompanying drawings.

According to one embodiment, a semiconductor device includes: a semiconductor substrate having an upper surface and a lower surface; a first conductive layer formed above the semiconductor substrate; and a second conductive layer formed on an upper surface of the first conductive layer, in which, when viewed from above, the second conductive layer is formed in a region inside an end edge of the first conductive layer, a thickness of the second conductive layer is larger than a thickness of the first conductive layer, a thermal conductivity of the second conductive layer is larger than a thermal conductivity of the first conductive layer, and a resistivity of the second conductive layer is smaller than a resistivity of the first conductive layer.

According to one embodiment, a semiconductor device includes: a semiconductor substrate having an upper surface and a lower surface; a first conductive layer formed above the semiconductor substrate; and a second conductive layer formed on an upper surface of the first conductive layer, in which, when viewed from above, the second conductive layer is formed in a region inside an end edge of the first conductive layer, and the second conductive layer has a plurality of fins extending in one direction in a plane parallel to the upper surface of the first conductive layer.

According to the above embodiment, it is possible to provide a semiconductor device capable of suppressing heat generation.

### BRIEF DESCRIPTION OF THE DRAWINGS

FIG. 1 is a plan view illustrating a semiconductor device according to a comparative example.

FIG. 2 is a cross-sectional view illustrating the semiconductor device according to the comparative example, and showing a cross section taken along line II-II in FIG. 1.

FIG. 3 is a plan view illustrating a semiconductor device according to a first embodiment.

FIG. is 4 cross-sectional view (illustrating the semiconductor device according to the first embodiment, and showing a cross section taken along line IV-IV in FIG. 3.

FIG. 5 is a plan view illustrating a plurality of pad portions on a conductive layer of a device unit in the semiconductor device according to the first embodiment.

FIG. 6 is a plan view illustrating the semiconductor device according to the first embodiment.

FIG. 7 is a cross-sectional view illustrating the semiconductor device according to the first embodiment, and showing a cross section taken along line VII-VII in FIG. 6.

FIG. 8 is a cross-sectional view illustrating the semiconductor device according to the first embodiment.

FIG. 9 is a cross-sectional view illustrating the semiconductor device according to the first embodiment.

FIG. 10 is a cross-sectional view illustrating the

FIG. 11 is a cross-sectional view illustrating the semiconductor device according to the first embodiment. semiconductor device according to the first embodiment.

FIG. 12 is a cross-sectional view illustrating the semiconductor device according to the first embodiment.

FIG. 13 is a plan view illustrating a semiconductor device according to a second embodiment.

FIG. 14 is a plan view illustrating the semiconductor device according to the second embodiment.

FIG. 15 is a cross-sectional view illustrating the semiconductor device according to the second embodiment, and showing a cross section taken along line XV-XV in FIG. 14.

FIG. 16 is a cross-sectional view illustrating the

FIG. 17 is a cross-sectional view illustrating the semiconductor device according to the second embodiment.

FIG. 18 is a cross-sectional view illustrating the semiconductor device according to the second embodiment. semiconductor device according to the second embodiment.

FIG. 19 is a cross-sectional view illustrating the semiconductor device according to the second embodiment.

FIG. 20 is a cross-sectional view illustrating the semiconductor device according to the second embodiment.

### DETAILED DESCRIPTION

For clarity of description, the following description and drawings are omitted and simplified as appropriate. In the drawings, the same elements are denoted by the same reference numerals, and redundant description is omitted as necessary.

First, a semiconductor device according to a comparative example will be described in <Comparative Example>. Thereafter, in <Problem Newly Found by Inventor>, problems newly found by the inventor with respect to the semiconductor device of the comparative example will be described. Then, in <First Embodiment>and <Second Embodiment>, a semiconductor device according to each embodiment will be described. Thus, the semiconductor device according to each embodiment will be made clearer. Note that the semiconductor device according to the comparative example, and the problems newly found by the inventor are also within the scope of the technical idea of the embodiment.

<Comparative Example>

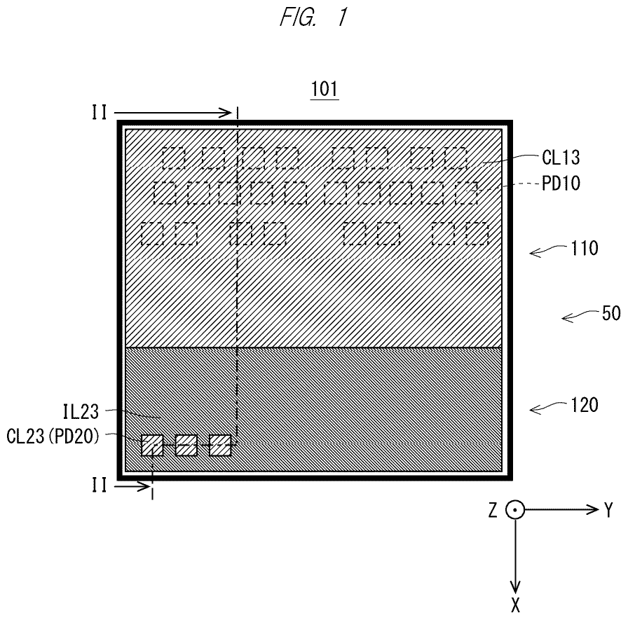

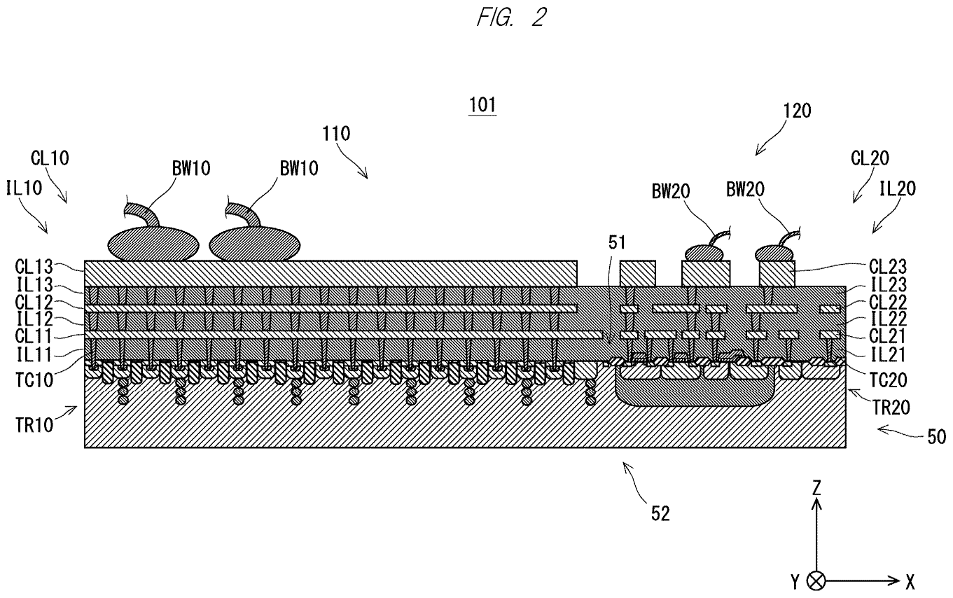

The semiconductor device according to the comparative example will be described. FIG. 1 is a plan view illustrating a semiconductor device 101 according to the comparative example. FIG. 2 is a cross-sectional view illustrating the semiconductor device 101 according to the comparative example, and showing a cross section taken along line II-II in FIG. 1. In the following drawings including FIGS. 1 and 2, some reference numerals are omitted so as not to complicate the drawings. In addition, in the following plan views including FIG. 1, bonding wires BW10 and BW20 may be omitted. As illustrated in FIGS. 1 and 2, the semiconductor device 101 according to the comparative example includes a semiconductor substrate 50 as a substrate. In the following description, the semiconductor substrate 50 will be used as the substrate of the semiconductor device 101. Note that the substrate is not necessarily limited to the semiconductor substrate 50. The semiconductor substrate 50 has a plate shape and has plate surfaces on both sides. The semiconductor substrate 50 has one plate surface and the other plate surface opposite to the one plate surface.

Here, an XYZ orthogonal coordinate axis system is introduced for convenience of the description of the semiconductor device 101. A direction orthogonal to the one plate surface of the semiconductor substrate 50 is defined as a Z-axis direction. Then, one direction is defined as a +Z-axis direction, and the other is defined as a −Z-axis direction. Two directions orthogonal to the Z-axis direction and orthogonal to each other are defined as an X-axis direction and a Y-axis direction. For convenience of description, the +Z-axis direction is referred to as an upper side, and the −Z-axis direction is referred to as a lower side. Therefore, the one plate surface of the semiconductor substrate 50 is referred to as an upper surface 51, and the other plate surface is referred to as a lower surface 52. The semiconductor substrate 50 has the upper surface 51 and the lower surface 52. Note that the upper side, the lower side, the upper surface 51, and the lower surface 52 are for convenience of description, and do not indicate a direction in which the actual semiconductor device 101 is disposed.

When viewed from above, the semiconductor device 101 includes a power device unit 110 and a control circuit unit 120. Note that the outer frame indicates that a conductive layer CL13 and the like are not formed up to an end edge of the semiconductor device 101. Hereinafter, as an example, the power device unit 110 and the control circuit unit 120 of the semiconductor device 101 will be described as being formed on one semiconductor substrate 50 as in a monolithic intelligent power device (IPD), but the present invention is not limited thereto. For example, the power device unit 110 and the control circuit unit 120 of the semiconductor device 101 may be formed on different semiconductor substrates 50. That is, the power device unit 110 and the control circuit unit 120 may be individually configured as a single part. In addition, in the semiconductor device 101, the power device unit 110 and the control circuit unit 120 may be formed in a multi-chip module (MCM) type IPD in which a plurality of chips are stacked.

The power device unit 110 includes, for example, the semiconductor substrate 50, a device, an insulating layer IL10, a conductive layer CL10, and a through conductor TC10. In the power device unit 110, the device is formed on the semiconductor substrate 50. As an example, the power device includes a device constituting the IPD. Note that the power device is not limited to the IPD, and may be a single power device. The IPD may include a vertical power MOS transistor, specifically, a trench type metal oxide semiconductor field effect transistor (trench MOSFET), formed on the semiconductor substrate 50. As such, the device may include a transistor TR10 formed on the semiconductor substrate 50. Note that the power device unit 110 may be simply referred to as a device unit, and in this case, the device of the device unit is not limited to the power device.

The power device unit 110 may include a plurality of transistors TR10, a plurality of insulating layers IL10, a plurality of conductive layers CL10, and a plurality of through conductors TC10. The plurality of transistors TR10 may be collectively referred to as the transistor TR10.

The power device unit 110 may include an insulating layer IL11, an insulating layer IL12, and an insulating layer IL13. Here, the plurality of insulating layers IL10 including the insulating layer IL11, the insulating layer IL12, and the insulating layer IL13 may be collectively referred to as the insulating layer IL10. Note that the power device unit 110 does not necessarily include three insulating layers IL10, and may include two or less insulating layers IL10 or may include four or more insulating layers IL10. The insulating layer IL10 is formed on the semiconductor substrate 50. The insulating layers IL10 of the plurality of insulating layers IL10 are alternately stacked with respective conductive layers CL of the plurality of conductive layers CL10 on the semiconductor substrate 50.

The power device unit 110 may include a conductive layer CL11, a conductive layer CL12, and the conductive layer CL13. Here, the plurality of conductive layers CL10 including the conductive layer CL11, the conductive layer CL12, and the conductive layer CL13 may be collectively referred to as the conductive layer CL10. Note that the power device unit 110 does not necessarily include three conductive layers CL10, and may include two or less conductive layers CL10 or may include four or more conductive layers CL10. The conductive layer CL10 is formed on the semiconductor substrate 50. Conductive layers CL10 of the plurality of conductive layers CL10 are alternately stacked with respective insulating layers IL10 of the plurality of insulating layers IL10 on the semiconductor substrate 50.

For example, the insulating layer IL11 is disposed on the semiconductor substrate 50, and the conductive layer CL11 is disposed on the insulating layer IL11. The insulating layer IL12 is disposed on the conductive layer CL11, and the conductive layer CL12 is disposed on the insulating layer IL12. The insulating layer IL13 is disposed on the conductive layer CL12, and the conductive layer CL13 is disposed on the insulating layer IL13.

The power device unit 110 may include the plurality of through conductors TC10. Here, the plurality of through conductors TC10 may be collectively referred to as the through conductor TC10. In addition, the through conductor TC10 may be referred to as a via conductor. Each through conductor TC10 of the plurality of through conductors TC10 is formed on the semiconductor substrate 50. Each through conductor TC10 is disposed inside a through hole penetrating the insulating layer IL10. The through conductor TC10 connects upper and lower conductive layers CL10 sandwiching the insulating layer IL10.

When the transistor TR10 of the power device unit 110 is a vertical power MOS transistor, the uppermost conductive layer CL13 of the conductive layer CL10 may be a source electrode. Therefore, a source of the transistor TR10 of the power device unit 110 is connected to the conductive layer CL13 via wiring including the through conductor TC10.

The control circuit unit 120 includes, for example, the semiconductor substrate 50, a control circuit, an insulating layer IL20, a conductive layer CL20, and a through conductor TC20. The control circuit unit 120 includes a control circuit formed on the semiconductor substrate 50. The control circuit controls the device of the power device unit 110. In this manner, in the control circuit unit 120, the control circuit that controls the device of the power device unit 110 is formed on the semiconductor substrate 50. As an example, the control circuit includes a planar MOSFET such as a complementary MOS (CMOS) and a laterally diffused MOS (LDMOS). That is, the control circuit may include the transistor TR20. Therefore, in the control circuit unit 120, the transistor TR20 is formed on the semiconductor substrate 50.

The control circuit unit 120 may include a plurality of transistors TR20, a plurality of insulating layers IL20, a plurality of conductive layers CL20, and a plurality of through conductors TC20. The plurality of transistors TR20 may be collectively referred to as the transistor TR20.

The control circuit unit 120 may include an insulating layer IL21, an insulating layer IL22, and an insulating layer IL23. Here, the plurality of insulating layers IL20 including the insulating layer IL21, the insulating layer IL22, and the insulating layer IL23 may be collectively referred to as the insulating layer IL20. Note that the control circuit unit 120 does not necessarily include three insulating layers IL20, and may include two or less insulating layers IL20 or may include four or more insulating layers IL20. The insulating layer IL20 is formed on the semiconductor substrate 50. Insulating layers IL20 of the plurality of insulating layers IL20 are alternately stacked with respective conductive layers CL20 of the plurality of conductive layers CL20 on the semiconductor substrate 50.

The control circuit unit 120 may include a conductive layer CL21, a conductive layer CL22, and a conductive layer CL23. Here, the plurality of conductive layers CL20 including the conductive layer CL21, the conductive layer CL22, and the conductive layer CL23 may be collectively referred to as the conductive layer CL20. Note that the control circuit unit 120 does not necessarily include three conductive layers CL20, and may include two or less conductive layers CL20 or may include four or more conductive layers CL20. The conductive layer CL20 is formed on the semiconductor substrate 50. Conductive layers CL20 of the plurality of conductive layers CL20 are alternately stacked with respective insulating layers IL20 of the plurality of insulating layers IL20 on the semiconductor substrate 50.

For example, the insulating layer IL21 is disposed on the semiconductor substrate 50, and the conductive layer CL21 is disposed on the insulating layer IL21. The insulating layer IL22 is disposed on the conductive layer CL21, and the conductive layer CL22 is disposed on the insulating layer IL22. The insulating layer IL23 is disposed on the conductive layer CL22, and the conductive layer CL23 is disposed on the insulating layer IL23.

The control circuit unit 120 may include the plurality of through conductors TC20. Here, the plurality of through conductors TC20 may be collectively referred to as the through conductor TC20. Each through conductor TC20 of the plurality of through conductors TC20 is formed on the semiconductor substrate 50. Each through conductor TC20 is disposed inside a through hole penetrating the insulating layer IL20. The through conductor TC20 connects upper and lower conductive layers CL20 sandwiching the insulating layer IL20.

Each layer of the conductive layer CL10 of the power device unit 110 and each layer of the conductive layer CL20 of the control circuit unit 120 may include a portion having the same height from the upper surface 51 of the semiconductor substrate 50. For example, the conductive layer CL11 may include a portion having the same height from the upper surface 51 of the semiconductor substrate 50 as the conductive layer CL21. The conductive layer CL12 may include a portion having the same height from the upper surface 51 of the semiconductor substrate 50 as the conductive layer CL22. The conductive layer CL13 may include a portion having the same height from the upper surface 51 of the semiconductor substrate 50 as the conductive layer CL23. For example, each layer of the conductive layer CL10 may be formed in the same process step as that of each layer of the conductive layer CL20. Specifically, for example, each layer of the conductive layer CL10 may be formed at the same time as when each layer of the conductive layer CL20 is formed.

Each layer of the insulating layer IL10 of the power device unit 110 and each layer of the insulating layer IL20 of the control circuit unit 120 may include a portion having the same height from the upper surface 51 of the semiconductor substrate 50. For example, the insulating layer IL11 may include a portion having the same height from the upper surface 51 of the semiconductor substrate 50 as the insulating layer IL21. The insulating layer IL12 may include a portion having the same height from the upper surface 51 of the semiconductor substrate 50 as the insulating layer IL22. The insulating layer IL13 may include a portion having the same height from the upper surface 51 of the semiconductor substrate 50 as the insulating layer IL23. For example, each layer of the insulating layer IL10 may be formed in the same process step as that of each layer of the insulating layer IL20. Specifically, for example, each layer of the insulating layer IL10 may be formed at the same time as when each layer of the insulating layer IL20 is formed.

As can be seen when the semiconductor substrate 50 is viewed from above, a plurality of pad portions PD10 are set on an upper surface of the conductive layer CL13 of the power device unit 110. The pad portion PD10 may not be clearly distinguished in appearance when a cover film to be described later is not formed. In this manner, a region where the conductive layer CL13 is formed has the plurality of pad portions PD10. The bonding wire BW10 is connected to the pad portion PD10. That is, the bonding wires BW10 of a plurality of bonding wires BW10 are connected to respective pad portions PD10 of the plurality of pad portions PD10.

Each bonding wire BW10 may be connected to each pad portion PD10 of all the pad portions PD10 set on the upper surface of the conductive layer CL13, or each bonding wire BW10 may be connected to some of the pad portions PD10 of the pad portions PD10 set on the upper surface of the conductive layer CL13. Note that the plurality of bonding wires BW10 may be connected to one predetermined pad portion PD10, or there may be a pad portion PD10 to which the bonding wire BW10 is not connected.

When viewed from above, each pad portion PD10 is disposed in the region where the conductive layer CL13 is formed, and the pad portions PD10 are dispersed with a bias.

The conductive layer CL23 of the control circuit unit 120 includes a plurality of pad portions PD20. In the control circuit unit 120, a plurality of conductive layers CL23 may be formed on the insulating layer IL23. The conductive layers CL23 may correspond to respective pad portions PD20. The bonding wire BW20 is connected to the pad portion PD20. The bonding wire BW20 of the control circuit unit 120 may be referred to as a control bonding wire to distinguish it from the bonding wire BW10 of the power device unit 110. Each bonding wire BW20 of a plurality of bonding wires BW20 is connected to each pad portion PD20 of the plurality of pad portions PD20.

Each bonding wire BW20 may be connected to each pad portion PD20 of all the pad portions PD20 formed from the plurality of conductive layers CL23, or each bonding wire BW20 may be connected to some of the pad portions PD20 of the pad portions PD20 of the conductive layer CL23. Note that the plurality of bonding wires BW20 may be connected to one predetermined pad portion PD20. In addition, there may be a pad portion PD20 to which the bonding wire BW20 is not connected.

### Problem Newly Found by Inventor

The semiconductor device 101 causes a current to flow to the transistor TR10 of the power device unit 110 via the bonding wire BW10. In addition, the semiconductor device 101 causes a current to flow to the transistor TR20 of the control circuit unit 120 via the bonding wire BW20. Thus, the semiconductor device 101 can be operated.

When a large current flows through the semiconductor device 101, the semiconductor device 101 may generate heat. For example, when a large current flows through the transistor TR10 such as the power MOS of the power device unit 110 via the bonding wire BW10, the pad portion PD10 of the conductive layer CL13 has a large local current density as compared with the periphery. As a result, the semiconductor device 101 generates heat. It is conceivable to increase the thickness of the conductive layer CL10 to suppress heat generation of the semiconductor device 101. However, when the thickness of the conductive layer CL10 is simply increased, the size of the semiconductor device 101 is increased, and in addition, the effect of suppressing the heat generation may not be obtained so much.

In response to this, we attempted to reduce the heat generation of the semiconductor device by changing the material functioning as the conductive layer to a material having thermal conductivity larger than that of the conductive layer CL10 and adding the material having thermal conductivity larger than that of the conductive layer CL10 onto the conductive layer CL10. With such a configuration, it is possible to suppress the heat generation of the semiconductor device.

### First Embodiment

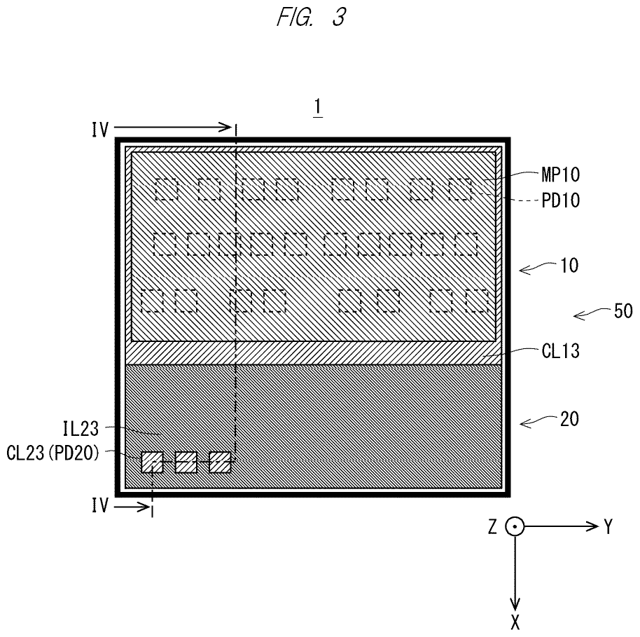

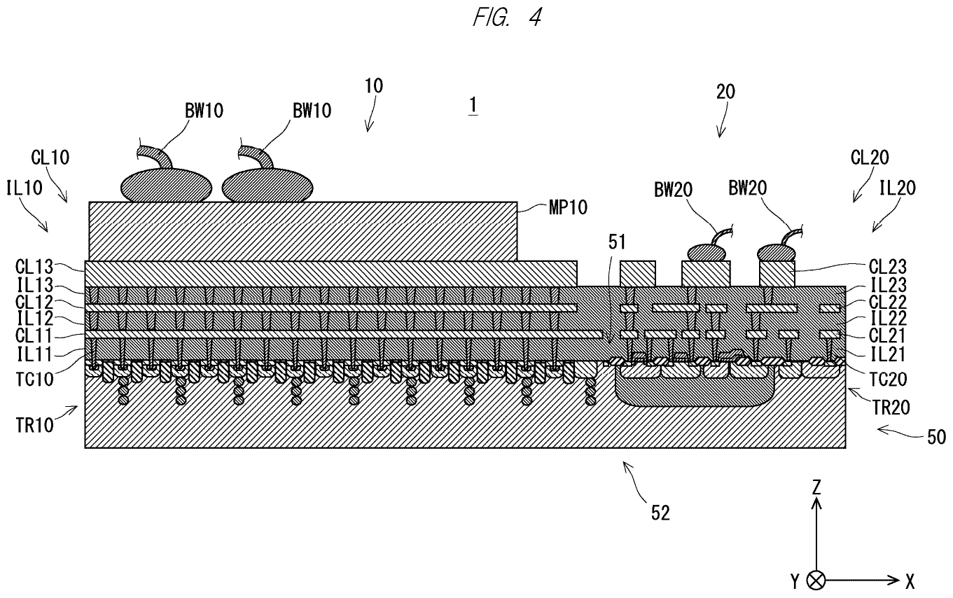

Next, a semiconductor device 1 according to a first embodiment will be described. FIG. 3 is a plan view illustrating the semiconductor device 1 according to the first embodiment. FIG. 4 is a cross-sectional view illustrating the semiconductor device 1 according to the first embodiment, and showing a cross section taken along line IV-IV in FIG. 3. As illustrated in FIGS. 3 and 4, the semiconductor device 1 of the present embodiment also includes the semiconductor substrate 50 as the substrate, similarly to the semiconductor device 101 of the comparative example. In addition, the semiconductor device 1 includes a power device unit 10 and a control circuit unit 20. Note that the outer frame indicates that a conductive layer MP10 and the like are not formed up to an end edge of the semiconductor device 1.

The power device unit 10 further includes the conductive layer MP10 in addition to the power device unit 110 of the comparative example. The conductive layer MP10 is formed on the upper surface of the conductive layer CL13. Specifically, the conductive layer MP10 is formed in a layer shape on the upper surface of the conductive layer CL13 so as to be in contact with the upper surface of the conductive layer CL13. Thus, the conductive layer MP10 is formed on the conductive layer CL13. The conductive layer CL13 may be referred to as a first conductive layer, and the conductive layer MP10 may be referred to as a second conductive layer. Therefore, the semiconductor device 1 includes the semiconductor substrate 50 having the upper surface 51 and the lower surface 52, the first conductive layer formed above the semiconductor substrate 50, and the second conductive layer formed on the upper surface of the first conductive layer. When viewed from above, the conductive layer MP10 is formed in a region inside an end edge of the conductive layer CL13. As an example, when the conductive layer MP10 is formed on the conductive layer CL13 by plating, a mask is placed to overlap the conductive layer CL13. The conductive layer MP10 is formed in a portion not covered with the mask on the conductive layer CL13. Thus, the conductive layer MP10 is formed in the region inside the end edge of the conductive layer CL13. Note that the method of forming the conductive layer MP10 on the conductive layer CL13 is not limited to plating.

The thickness of the conductive layer MP10 is preferably larger than the thickness of the conductive layer CL13. The thermal conductivity of the conductive layer MP10 is preferably larger than the thermal conductivity of the conductive layer CL13. The resistivity of the conductive layer MP10 is preferably smaller than the resistivity of the conductive layer CL13. With such a configuration, it is possible to promote heat dissipation at the conductive layer CL13 and the conductive layer MP10 and to suppress heat generation of the semiconductor device 1.

For example, the conductive layer CL11, the conductive layer CL12, and the conductive layer CL13 may contain aluminum. On the other hand, the conductive layer MP10 may contain copper. In addition, the conductive layer MP10 may include a plating layer formed by plating. With such a configuration, it is possible to further promote the heat dissipation at the conductive layer CL13 and the conductive layer MP10 and to further suppress the heat generation of the semiconductor device 1.

The plurality of bonding wires BW10 are connected to a region of the power device unit 10 where the conductive layer MP10 is formed. In addition, the plurality of bonding wires BW20 are connected to a region of the control circuit unit 20 where the conductive layer CL23 is formed. The bonding wire BW20 of the control circuit unit 20 may be referred to as a control bonding wire to distinguish it from the bonding wire BW10 of the power device unit 10.

The thickness of the bonding wire BW10 of the power device unit 10 is preferably larger than the thickness of the bonding wire BW20 of the control circuit unit 20. A current flowing through the bonding wire BW10 is larger than a current flowing through the bonding wire BW20. Therefore, by making the thickness of the bonding wire BW10 of the power device unit 10 larger than the thickness of the bonding wire BW20 of the control circuit unit 20, it is possible to reduce the density of a current flowing through the bonding wire BW10 and to suppress the heat generation of the semiconductor device 1.

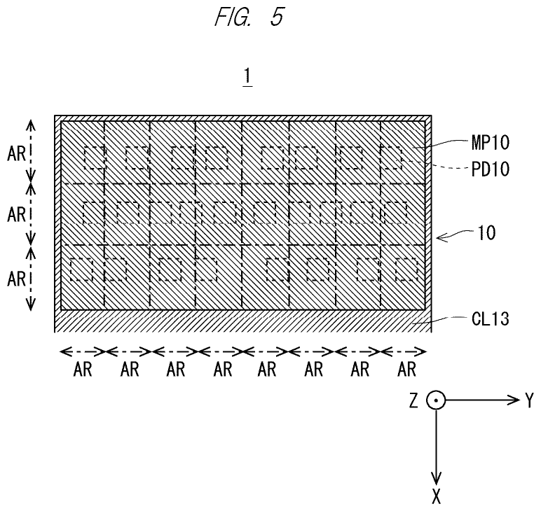

FIG. 5 is a plan view illustrating the plurality of pad portions PD10 on the conductive layer MP10 of the power device unit 10 in the semiconductor device 1 according to the first embodiment. As illustrated in FIG. 5, the pad portions PD10 are dispersedly disposed in the region where the conductive layer MP10 is formed. That is, the pad portions PD10 are dispersed without a bias on the conductive layer MP10. Specifically, when viewed from above, the region where the conductive layer MP10 is formed includes the plurality of pad portions PD10 to which respective bonding wires BW of the plurality of bonding wires BW are connected. In addition, in the arrangement in FIG. 5, the pad portions PD10 are evenly dispersed without a bias also in the X direction, as compared with the arrangement in FIG. 1. When the region where the conductive layer MP10 is formed is divided into several areas AR, each area AR includes at least one pad portion PD10. Note that each area AR has the same shape and the same size. With such a configuration, it is possible to disperse currents flowing into the conductive layer MP10 and flowing out of the conductive layer MP via the bonding wire BW10 and to relax concentration of the currents. Therefore, it is possible to suppress the heat generation of the semiconductor device 1.

The control circuit unit 20 may have the same configuration as the control circuit unit 120 of the comparative example. The conductive layer CL23 may be referred to as a third conductive layer. Therefore, the control circuit unit 20 includes the semiconductor substrate 50, the control circuit, and the third conductive layer formed above the semiconductor substrate 50 and including a portion having the same height from the upper surface 51 of the semiconductor substrate 50 as the first conductive layer.

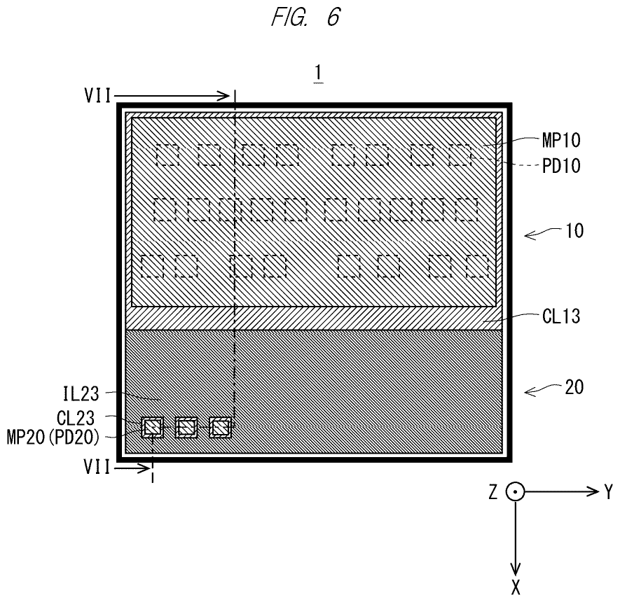

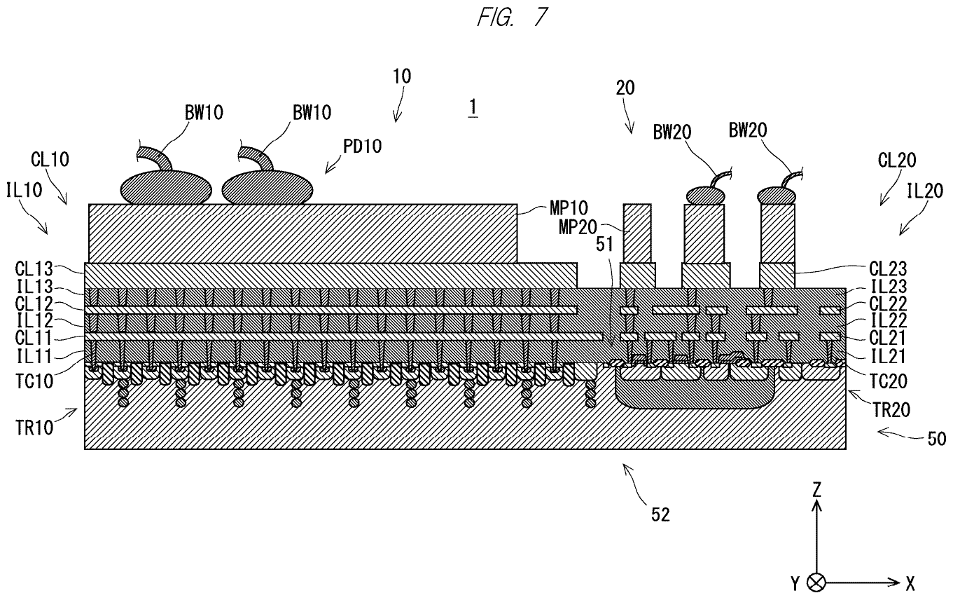

FIG. 6 is a plan view illustrating the semiconductor device 1 according to the first embodiment. FIG. 7 is a cross-sectional view illustrating the semiconductor device 1 according to the first embodiment, and showing a cross section taken along line VII-VII in FIG. 6. As illustrated in FIGS. 6 and 7, the semiconductor device 1 may further include a conductive layer MP20 in the control circuit unit 20. The conductive layer MP20 may be referred to as a fourth conductive layer. The conductive layer MP20 is formed on an upper surface of the conductive layer CL23. Specifically, the conductive layer MP20 is formed in a layer shape on the upper surface of the conductive layer CL23 so as to be in contact with the upper surface of the conductive layer CL23. Thus, the conductive layer MP20 is formed on the conductive layer CL23. The conductive layer MP20 may include a portion having the same height from the upper surface 51 of the semiconductor substrate 50 as the conductive layer MP10. For example, the conductive layer MP20 may be formed in the same process step as that of the conductive layer MP10. Specifically, the conductive layer MP20 may be formed in the same plating step as that of the conductive layer MP10 at the same time as when the conductive layer MP10 is formed.

When viewed from above, the conductive layer MP20 may be formed in a region inside an end edge of the conductive layer CL23. For example, the conductive layer MP20 may contain a plating layer. The bonding wire BW20 is connected to a region where the conductive layer CL24 is formed.

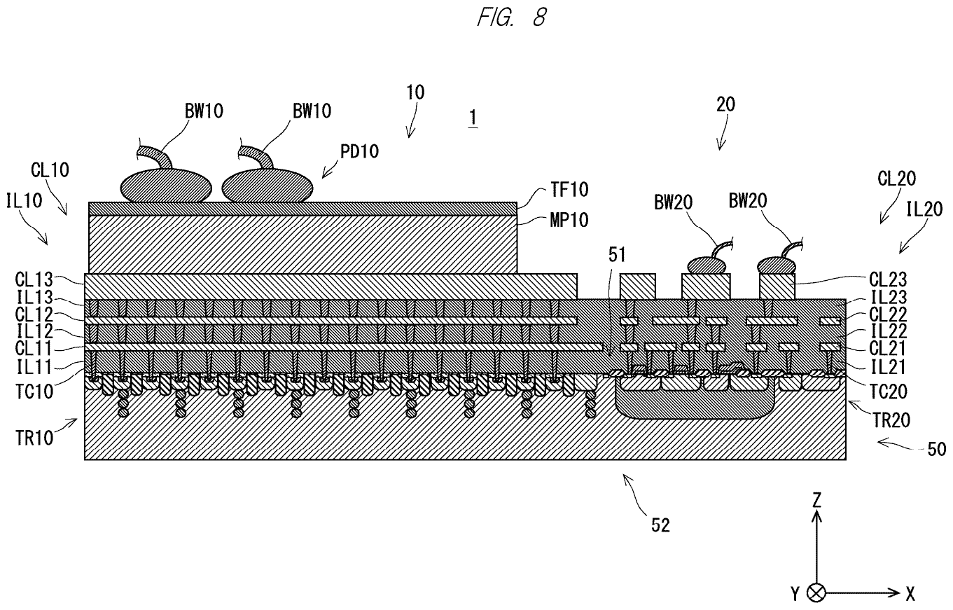

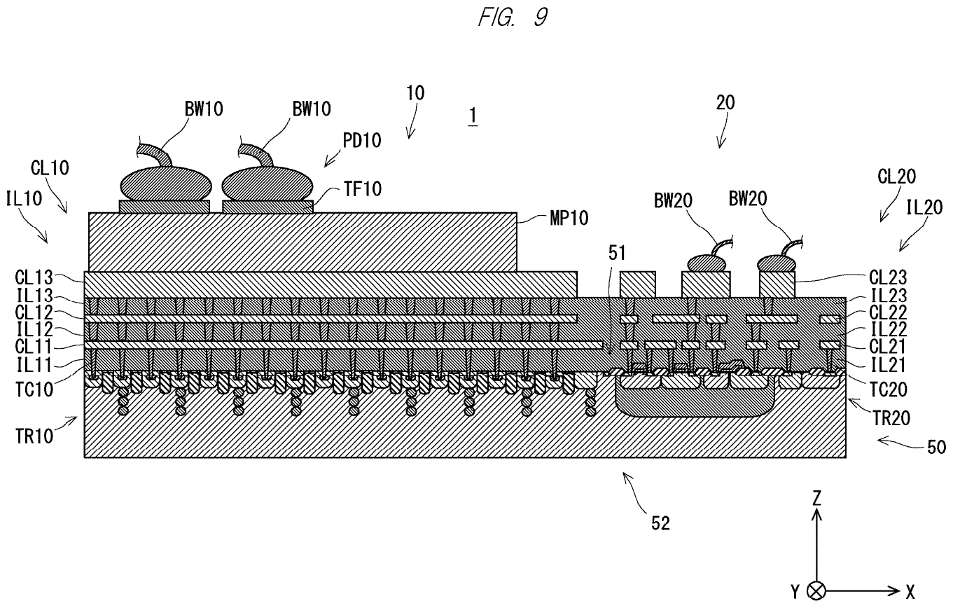

FIGS. 8 and 9 are cross-sectional views illustrating the semiconductor device 1 according to the first embodiment. As illustrated in FIGS. 8 and 9, the semiconductor device 1 may further include a conductive thin film TF10 in the power device unit 10. The conductive thin film TF10 is formed on an upper surface of the conductive layer MP10. Specifically, the conductive thin film TF10 is formed in a layer shape on the upper surface of the conductive layer MP10 so as to be in contact with the upper surface of the conductive layer MP10. Thus, the conductive thin film TF10 is stacked on the conductive layer MP10.

The conductive layer MP10 is connected to the bonding wire BW10 with the conductive thin film TF10 sandwiched therebetween. The conductive thin film TF10 can improve the bonding property of the bonding wire BW10. The conductive thin film CF10 may contain, for example, at least one of nickel, palladium, and gold.

As illustrated in FIG. 8, the conductive thin film TF10 may be formed on the entire upper surface of the conductive layer MP10, or as illustrated in FIG. 9, the conductive thin film TF10 may be formed on a part of the upper surface of the conductive layer MP10. The “part” includes, for example, a region of the pad portion PD10. By forming the conductive thin film TF10 at least in a region of the pad portion PD10 on the upper surface of the conductive layer MP10, the bonding property of the bonding wire BW10 can be improved.

Note that the conductive thin film TF10 may be formed on the upper surface of the conductive layer CL23 or an upper surface of the conductive layer MP20 of the control circuit unit 20. Thus, the bonding property of the bonding wire BW20 can be improved.

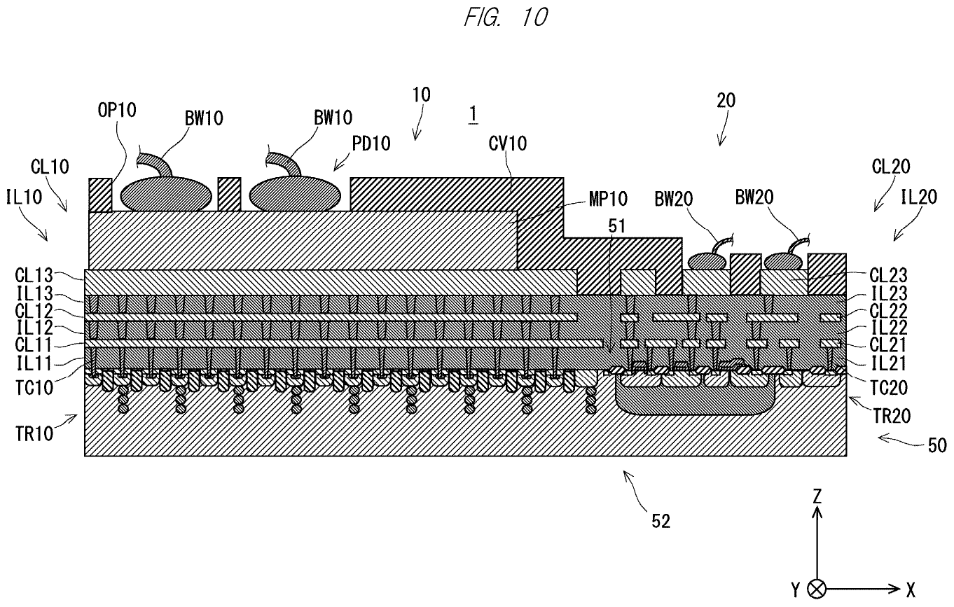

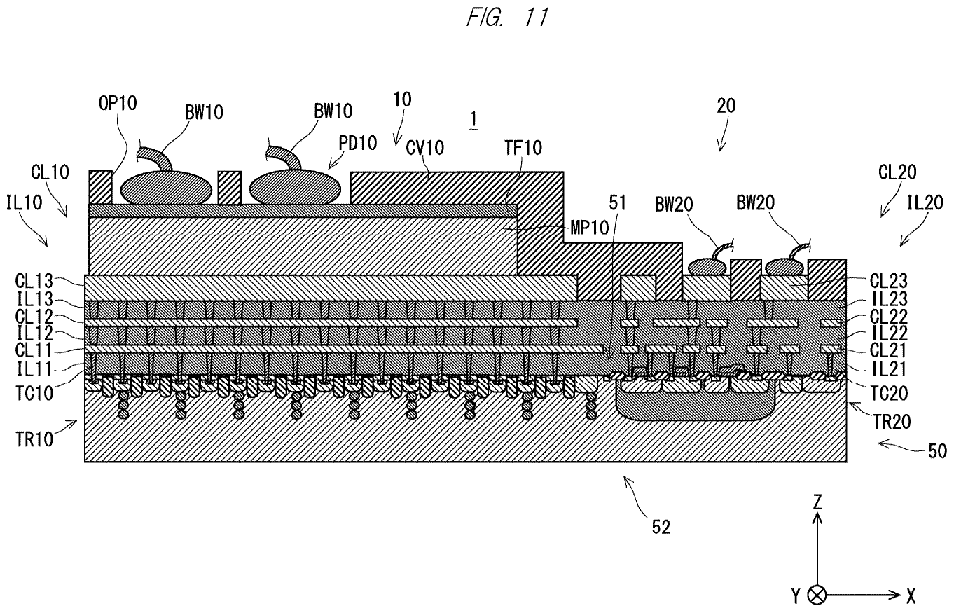

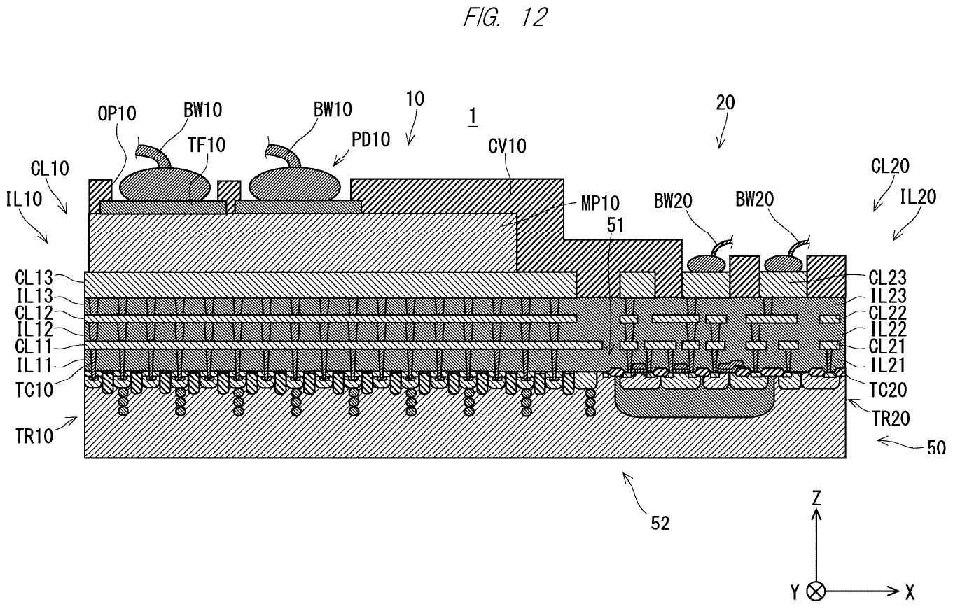

FIGS. 10 to 12 are cross-sectional views illustrating the semiconductor device 1 according to the first embodiment. As illustrated in FIGS. 10 to 12, the semiconductor device 1 may further include a cover film CV10. As illustrated in FIG. 10, the cover film CV10 may be formed so as to cover the conductive layer MP10, or as illustrated in FIG. 11, may be formed so as to cover the conductive layer MP10 and the conductive thin film TF10. Also when the cover film CV10 is formed, as illustrated in FIGS. 11 and 12, the conductive thin film TF10 may be formed on the entire upper surface of the conductive layer MP10, or may be formed on a part of the upper surface of the conductive layer MP10. The “part” includes, for example, a region of the pad portion PD10.

The cover film CV10 includes a plurality of openings OP10. Each opening OP10 corresponds to each pad portion PD10. Therefore, the bonding wire BW10 is connected to the pad portion PD10 exposed through the opening OP10 of the cover film CV10. The cover film CV10 may contain, for example, polyimide.

Note that the cover film CV10 may be formed so as to cover the conductive layer CL23 of the control circuit unit 20, or may be formed so as to cover the conductive layer CL23 and the conductive layer MP20. Furthermore, the cover film CV10 may be formed so as to cover the conductive layer CL23, or the conductive layer CL23 and the conductive layer MP20 of the control circuit unit 20. The bonding wire BW20 of the control circuit unit 20 is connected to the pad portion PD20 exposed through the opening OP10 of the cover film CV10 of the control circuit unit 20.

Next, effects of the present embodiment will be described. The semiconductor device 1 of the present embodiment includes the conductive layer MP10 formed on the upper surface of the conductive layer CL13. As a result, it is possible to improve the heat dissipation of the semiconductor device 1 and suppress the heat generation. In addition, the thickness of the conductive layer MP10 may be larger than the thickness of the conductive layer CL13, the thermal conductivity of the conductive layer MP10 may be larger than the thermal conductivity of the conductive layer CL13, and the resistivity of the conductive layer MP10 may be smaller than the resistivity of the conductive layer CL13. Therefore, it is possible to further suppress the heat generation of the semiconductor device 1.

The plurality of pad portions PD10 may be dispersedly disposed. As a result, it is possible to disperse a current flowing through the semiconductor device 1 and to reduce the current density. Therefore, it is possible to reduce the heat generation of the semiconductor device 1. In addition, the thickness of the bonding wire BW10 of the power device unit 10 may be larger than the thickness of the bonding wire BW20 of the control circuit unit 20. With such a configuration, it is possible to further reduce the heat generation of the semiconductor device 1.

### Second Embodiment

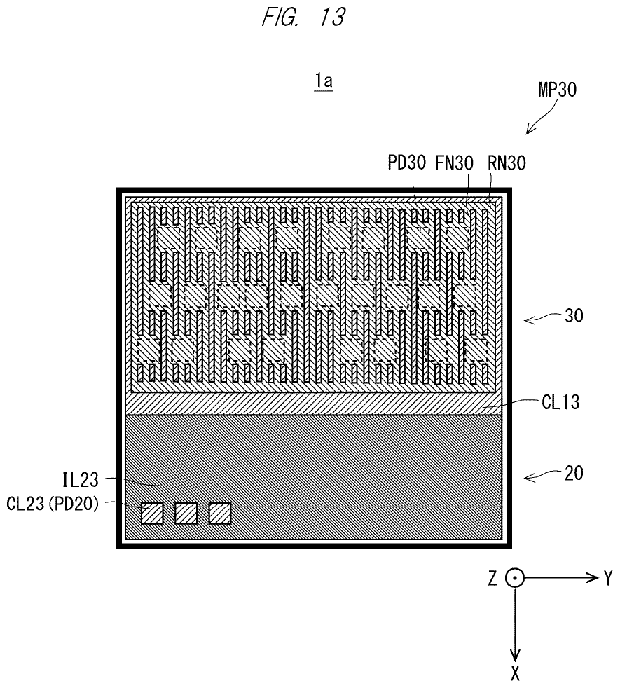

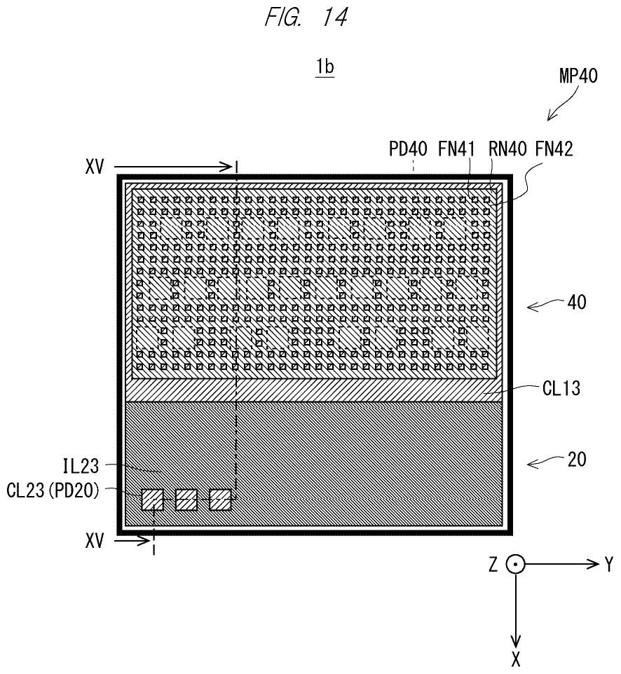

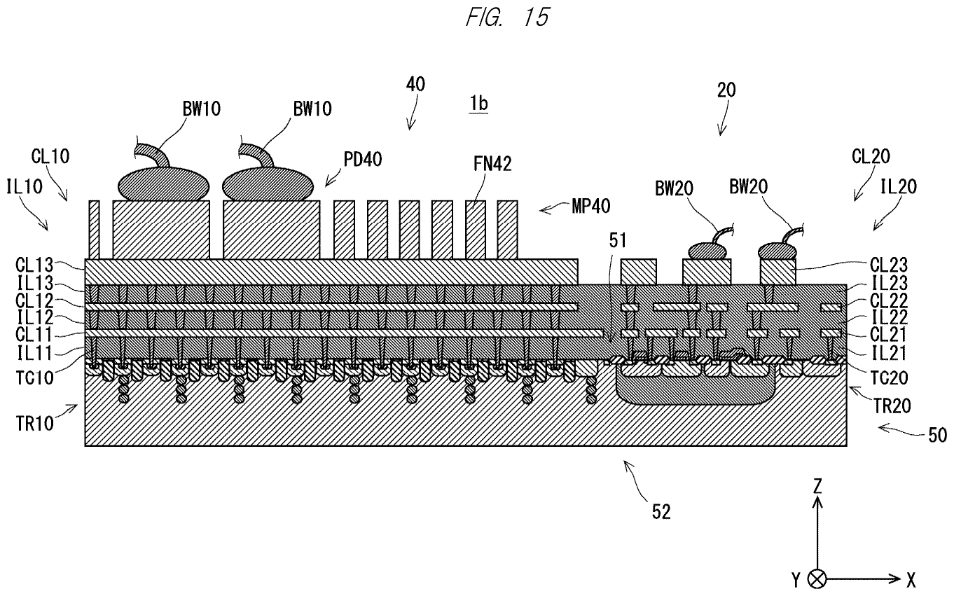

Next, a semiconductor device according to a second embodiment will be described. In the semiconductor device of the present embodiment, a conductive layer having fins is formed. FIG. 13 is a plan view illustrating a semiconductor device 1a according to the second embodiment. FIG. 14 is a plan view illustrating a semiconductor device 1b according to the second embodiment. FIG. 15 is a cross-sectional view illustrating the semiconductor device 1b according to the second embodiment, and showing a cross section taken along line XV-XV in FIG. 14. In FIGS. 14 and 15, the number and intervals of fins FN42 in FIG. 14 do not correspond to the number and intervals of the fins FN42 in FIG. 15 so as not to complicate the drawing.

As illustrated in FIG. 13, the semiconductor device la of the present embodiment includes a power device unit 30 and the control circuit unit 20. The power device unit 30 further includes a conductive layer MP30 in addition to the power device unit 110 of the comparative example. The conductive layer MP30 is formed on the upper surface of the conductive layer CL13. The conductive layer MP30 includes a plurality of fins FN30, a plurality of pad portions PD30, and an annular portion RN30.

The fin FN30 extends in one direction in a plane parallel to the upper surface of the conductive layer CL13. The fin FN30 extends, for example, in the X-axis direction. Note that the fin FN30 may extend in the Y-axis direction or may extend in a direction inclined from the X-axis direction and the Y-axis direction. A lower surface of the fin FN30 is in contact with the conductive layer CL13. The plurality of fins FN30 are adjacent to each other in the Y-axis direction, for example. A groove is formed between the fins FN30 and FN30 adjacent to each other. The groove between the fin FN30 and the fin FN30 extends in the X-axis direction. The groove between the fin FN30 and the fin FN30 penetrates from an upper surface to a lower surface of the conductive layer MP30.

Respective bonding wires of the plurality of bonding wires BW10 are connected to the pad portion PD30. Some fins FN30 of the plurality of fins FN30 may extend in the X-axis direction from the pad portion PD30. Specifically, the fin FN30 may include a portion extending from the pad portion PD30 to the +X-axis direction side and the −X-axis direction side in the X-axis direction. In addition, some fins FN30 may not be connected to the pad portion PD30.

The annular portion RN30 is formed in an annular shape. For example, the annular portion RN30 may be formed in an annular shape along the end edge of the conductive layer CL13. The plurality of fins FN30 and the plurality of pad portions PD30 are surrounded by the annular portion RN30. End portions of the fin FN30 on the +X-axis and −X-axis direction sides in the X-axis direction are connected to the annular portion RN30. Upper surfaces of the plurality of fins FN30, the plurality of pad portions PD30, and the annular portion RN30 may have the same height from the upper surface 51 of the semiconductor substrate 50. That is, the upper surfaces of the plurality of fins FN30, the plurality of pad portions PD30, and the annular portion RN30 may be positioned at the same height in the Z direction.

As illustrated in FIGS. 14 and 15, the semiconductor device 1b may include a power device unit 40 and the control circuit unit 20. The power device unit 40 further includes a conductive layer MP40 in addition to the power device unit 110 of the comparative example. The conductive layer MP40 is formed on the upper surface of the conductive layer CL13. In the semiconductor device 1b, the conductive layer MP40 includes a plurality of fins FN41, a plurality of fins FN42, a plurality of pad portions PD40, and an annular portion RN40.

The fin FN41 extends in one direction in a plane parallel to the upper surface of the conductive layer CL13. The fin FN41 extends, for example, in the X-axis direction. Note that the fin FN41 may extend in the Y-axis direction or may extend in a direction inclined from the X-axis direction and the Y-axis direction. The plurality of fins FN41 are adjacent to each other in the Y-axis direction.

The fin FN42 extends in the other direction intersecting one direction in a plane parallel to the upper surface of the conductive layer CL13. The fin FN42 extends, for example, in the Y-axis direction. Note that the fin FN42 may extend in the X-axis direction or may extend in a direction inclined from the X-axis direction and the Y-axis direction as long as it extends in a direction intersecting the fin FN41. The plurality of fins FN42 are adjacent to each other in the X-axis direction.

Lower surfaces of the fin FN41 and the fin FN42 are in contact with the conductive layer CL13. Holes are formed between the fins FN41 and FN41 adjacent to each other and between the fins FN42 and FN42 adjacent to each other. In this manner, the holes surrounded by the fins FN41 adjacent to each other and the fins FN42 adjacent to each other penetrate from an upper surface to a lower surface of the conductive layer MP40. With such a configuration, the fin FN41 and the fin FN42 have a mesh shape.

Respective bonding wires of the plurality of bonding wires BW10 are connected to the pad portion PD40. The fin FN41 includes a portion extending from the pad portion PD40 to the +X-axis direction side and the −X-axis direction side in the X-axis direction. The fin FN42 includes a portion extending from the pad portion PD40 to the +Y-axis direction side and the −Y-axis direction side in the Y-axis direction.

The annular portion RN40 is formed in an annular shape. The annular portion RN40 may be formed in an annular shape along the end edge of the conductive layer CL13, for example. The plurality of fins FN41, the plurality of fins FN42, and the plurality of pad portions PD40 are surrounded by the annular portion RN40. End portions of the fin FN41 on the +X-axis and −X-axis direction sides in the X-axis direction are connected to the annular portion RN40, and end portions of the fin FN42 on the +Y-axis and −Y-axis direction sides in the Y-axis direction are connected to the annular portion RN40.

Upper surfaces of the plurality of fins FN41, the plurality of fins FN42, the plurality of pad portions PD40, and the annular portion RN40 may have the same height from the upper surface 51 of the semiconductor substrate 50. That is, the upper surfaces of the plurality of fins FN41, the plurality of fins FN42, the plurality of pad portions PD40, and the annular portion RN40 may be positioned at the same height in the Z direction.

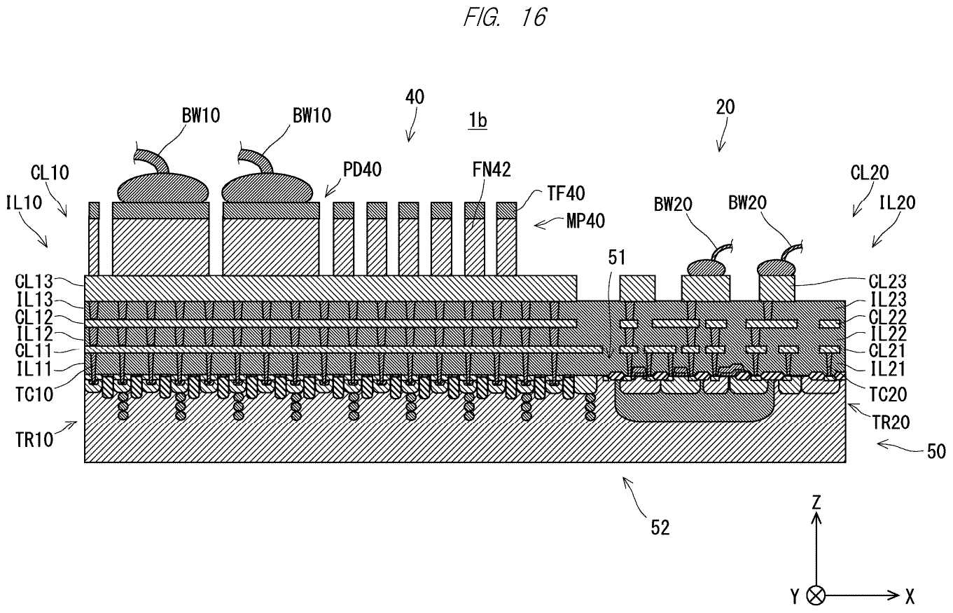

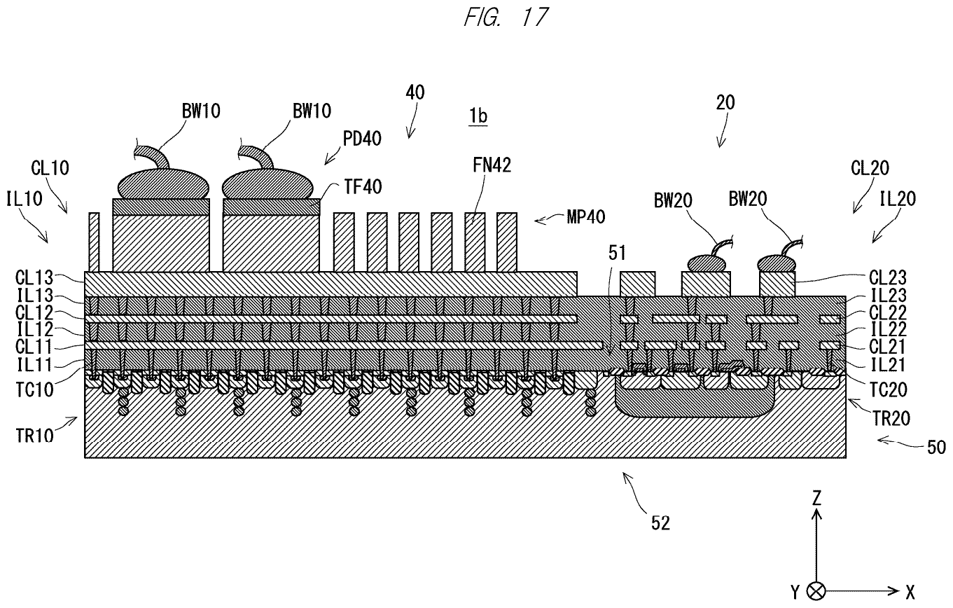

FIGS. 16 and 17 are cross-sectional views illustrating the semiconductor device 1b according to the second embodiment. As illustrated in FIGS. 16 and 17, the semiconductor device 1b further includes a conductive thin film TF40. The conductive thin film TF40 is formed on an upper surface of the conductive layer MP40. Specifically, the conductive thin film TF40 is formed in a layer shape on the upper surface of the conductive layer MP40 so as to be in contact with the upper surface of the conductive layer MP40. Thus, the conductive thin film TF40 is stacked on the conductive layer MP40. The conductive layer MP40 is connected to the bonding wire BW10 with the conductive thin film TF40 sandwiched therebetween.

As illustrated in FIG. 16, the conductive thin film TF40 may be formed on the entire upper surface of the conductive layer MP40, or as illustrated in FIG. 17, the conductive thin film TF40 may be formed on a part of the upper surface of the conductive layer MP40. The “part” includes, for example, a region of the pad portion PD40. By forming the conductive thin film TF40 at least in a region of the pad portion PD40 on the upper surface of the conductive layer MP40, the bonding property of the bonding wire BW10 can be improved.

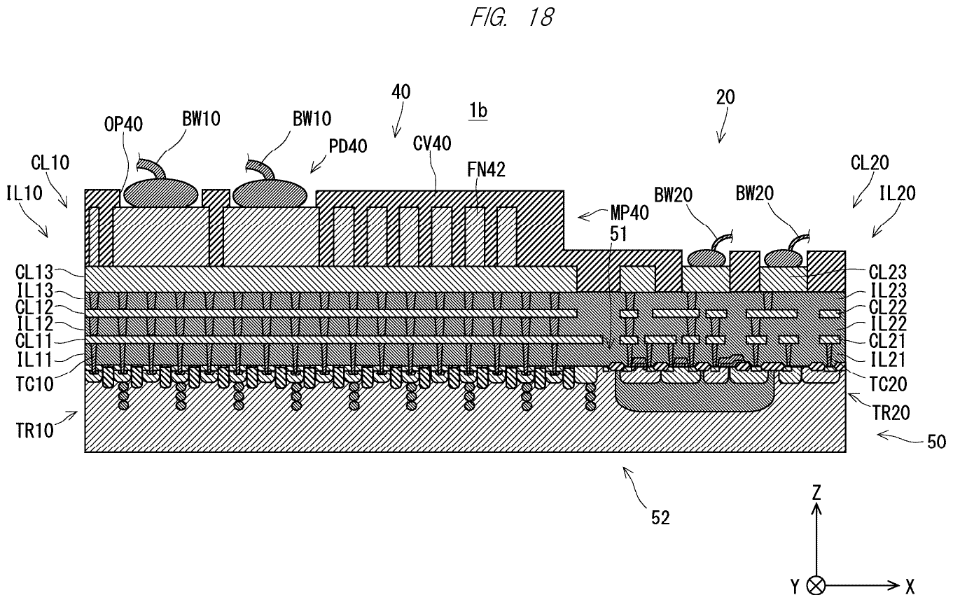

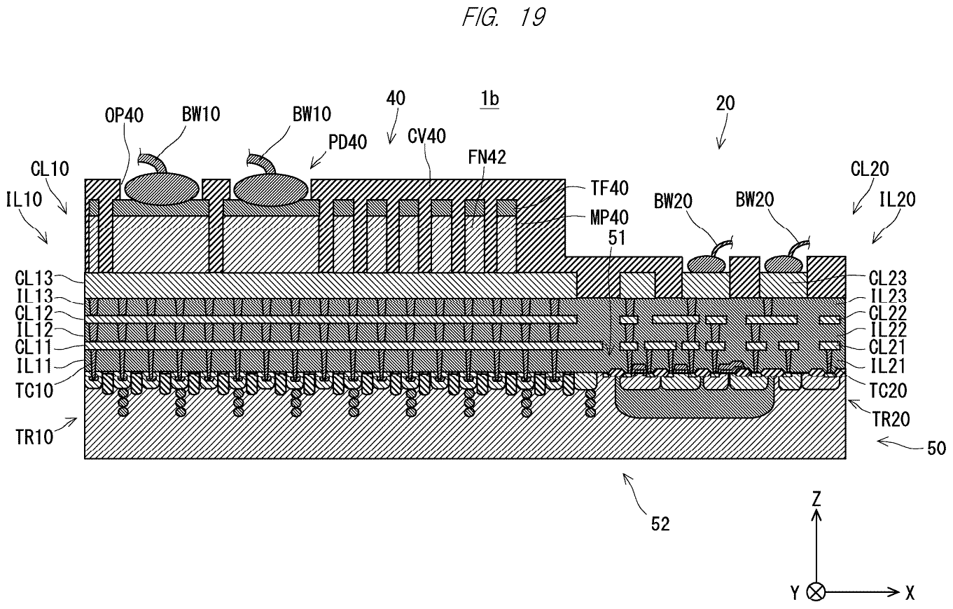

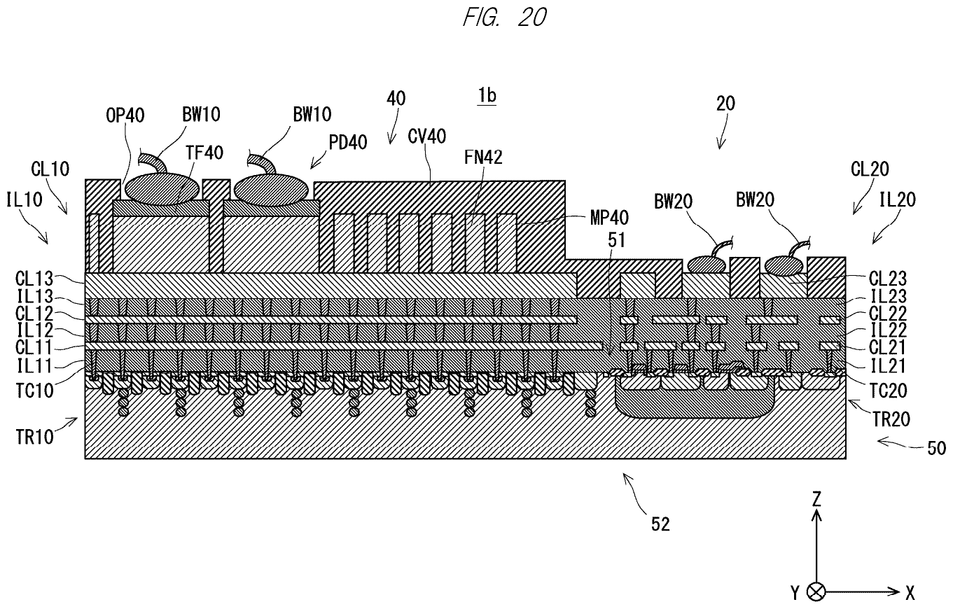

FIGS. 18 to 20 are cross-sectional views illustrating the semiconductor device 1b according to the second embodiment. As illustrated in FIGS. 18 to 20, the semiconductor device 1b may further include a cover film CV40. As illustrated in FIG. 18, the cover film CV40 may be formed so as to cover the fins FN41 and FN42 of the conductive layer MP40, or as illustrated in FIG. 19, the cover film CV40 may be formed so as to cover the fins FN41 and FN42 and the conductive thin film TF40 of the conductive layer MP40. Also when the cover film CV40 is formed, as illustrated in FIGS. 19 and 20, the conductive thin film TF40 may be formed on the entire upper surface of the conductive layer MP40, or may be formed on a part of the upper surface of the conductive layer MP40. The “part” includes, for example, a region of the pad portion PD40.

The cover film CV40 includes a plurality of openings OP40. Each opening OP40 corresponds to each pad portion PD40. Therefore, the bonding wire BW10 is connected to the pad portion PD40 exposed through the opening OP40 of the cover film CV40.

In the first embodiment and the second embodiment, the conductive layers MP10 to MP40 are connected to the bonding wires BW10 and BW20, but the present invention is not limited thereto. The conductive layers MP10 to MP40 may be connected to at least one of a clip, a ribbon, and a 2-stitch bonding wire.

Next, effects of the present embodiment will be described. In the semiconductor device 1a of the present embodiment, the fin FN30 is formed on the conductive layer MP30. In the semiconductor device 1b, fins FN41 and FN42 are formed on the conductive layer MP40. Since the fins FN30 and the like increase the heat dissipation area and improve the function of dissipating heat, it is possible to reduce heat generation of the semiconductor devices 1a and 1b.

In addition, since the heat dissipation function can be enhanced by including the fin FN30 or the like, the thicknesses of the conductive layer MP30 and the conductive layer MP40 can be made smaller than the thicknesses of the conductive layer MP10 and the conductive layer MP20 of the first embodiment. As a result, the conductive layer MP30 and the conductive layer MP40 can be suppressed from warping at the time of manufacturing.

By using a clip, a ribbon, a 2-stitch bonding wire, or the like instead of the bonding wires BW10 and BW20, these paths can be used as heat transfer paths. Therefore, it is possible to suppress local heat generation and suppress the heat generation of the semiconductor devices 1a and 1b and the like. Other configurations and effects are included in the description of the comparative example and the first embodiment.

Although the disclosure made by the present inventor has been specifically described based on the embodiments, it needless to say that the present disclosure is not limited to the above-described embodiments and comparative example can be made without departing from the gist of the present disclosure. For example, an appropriate combination of the configurations of the comparative example and the first to second embodiments is also within the scope of the technical idea of the embodiment. In addition, the following configurations are also within the scope of the technical idea of the embodiment.

(Appendix 21) The semiconductor device according to appendix 1, wherein the second conductive layer is connected to at least one of a clip, a ribbon, and a two-stitch bonding wire.

### (Appendix 22)

The semiconductor device according to appendix 1, wherein the semiconductor device is formed in an MCM-type IPD.

### (Appendix 23)

The semiconductor device according to appendix 1, further including a conductive thin film formed on an upper surface of the second conductive layer,
wherein the conductive thin film contains at least one of nickel, palladium, and gold.

### (Appendix 24)

The semiconductor device according to appendix 1,
wherein the first conductive layer contains aluminum, and
wherein the second conductive layer contains copper.

### (Appendix 25)

The semiconductor device according to appendix 1,
wherein, when viewed from above, a region where the second conductive layer is formed includes a plurality of pad portions to which respective bonding wires of a plurality of bonding wires are connected,
wherein the semiconductor device further includes a cover film formed so as to cover the second conductive layer,
wherein the cover film includes a plurality of openings,
wherein each opening corresponds to each pad portion, and
wherein the cover film contains polyimide.

What is claimed is:

1. A semiconductor device comprising:
a semiconductor substrate having an upper surface and a lower surface;
a first conductive layer formed above the semiconductor substrate; and
a second conductive layer formed on an upper surface of the first conductive layer,
wherein, when viewed from above, the second conductive layer is formed in a region inside an end edge of the first conductive layer,
wherein a thickness of the second conductive layer is larger than a thickness of the first conductive layer,
wherein a thermal conductivity of the second conductive layer is larger than a thermal conductivity of the first conductive layer, and
wherein a resistivity of the second conductive layer is smaller than a resistivity of the first conductive layer.

2. The semiconductor device according to claim 1,
wherein, when viewed from above, a region where the second conductive layer is formed includes a plurality of pad portions to which respective bonding wires of a plurality of bonding wires are connected, and
wherein, when the region where the second conductive layer is formed is divided into several areas, each area includes at least one pad portion.

3. The semiconductor device according to claim 2, comprising:
a device unit in which a device is formed on the semiconductor substrate; and
a control circuit unit in which a control circuit for controlling the device is formed on the semiconductor substrate,
wherein the device unit includes:
the semiconductor substrate;
the device;
the first conductive layer; and
the second conductive layer,
wherein the control circuit unit includes:
the semiconductor substrate;
the control circuit; and
a third conductive layer formed above the semiconductor substrate, the third conductive layer including a portion having the same height from the upper surface of the semiconductor substrate as the first conductive layer,
wherein, when viewed from above, a plurality of control bonding wires are connected to a region where the third conductive layer is formed, and
wherein a thickness of the bonding wire of the device unit is larger than a thickness of the control bonding wire of the control circuit unit.

4. The semiconductor device according to claim 3, further comprising a fourth conductive layer formed on an upper surface of the third conductive layer, the fourth conductive layer including a portion having the same height from the upper surface of the semiconductor substrate as the second conductive layer,
wherein, when viewed from above,
the fourth conductive layer is formed in a region inside an end edge of the third conductive layer, and
the control bonding wire is connected to a region where the fourth conductive layer is formed.

5. The semiconductor device according to claim 2, further comprising a conductive thin film formed on an upper surface of the second conductive layer
wherein the second conductive layer is connected to the bonding wire with the conductive thin film sandwiched therebetween.

6. The semiconductor device according to claim 2, further comprising a cover film formed so as to cover the second conductive layer,
wherein the cover film includes a plurality of openings, and
wherein each opening corresponds to each pad portion.

7. The semiconductor device according to claim 6, further comprising a conductive thin film formed on an upper surface of the second conductive layer,
wherein the cover film is formed so as to cover the second conductive layer and the conductive thin film.

8. The semiconductor device according to claim 3,
wherein the device unit includes a plurality of transistors, and
wherein a source of the transistor is connected to the first conductive layer via wiring including a via conductor.

9. The semiconductor device according to claim 3,
wherein the device unit includes a vertical power MOS transistor formed on the semiconductor substrate.

10. The semiconductor device according to claim 1,
wherein the second conductive layer includes a plating layer.

11. The semiconductor device according to claim 1,
wherein the second conductive layer includes a plurality of fins extending in one direction in a plane parallel to an upper surface of the first conductive layer.

12. The semiconductor device according to claim 11,
wherein the second conductive layer further includes a plurality of pad portions to which respective bonding wires of the plurality of bonding wires are connected, and
wherein the fin includes a portion extending from the pad portion to one side and another side in the one direction.

13. The semiconductor device according to claim 11,
wherein the second conductive layer further includes a plurality of fins extending in another direction intersecting the one direction in the plane parallel to the upper surface of the first conductive layer.

14. The semiconductor device according to claim 13,
wherein the second conductive layer further includes a plurality of pad portions to which respective bonding wires of the plurality of bonding wires are connected, and
wherein the fin includes:
a portion extending from the pad portion to one side and another side in the one direction; and
a portion extending from the pad portion to one side and another side in the other direction.

15. The semiconductor device according to claim 11,
wherein the second conductive layer includes an annular portion annularly formed along the end edge, and
wherein an end portion on one side and an end portion on another side in the one direction of the fin are connected to the annular portion.

16. The semiconductor device according to claim 12, further comprising a conductive thin film formed on an upper surface of the second conductive layer,
wherein the second conductive layer is connected to the bonding wire with the conductive thin film sandwiched therebetween.

17. The semiconductor device according to claim 12, further comprising a cover film formed so as to cover the second conductive layer,
wherein the cover film includes a plurality of openings, and
wherein each opening corresponds to each pad portion.

18. The semiconductor device according to claim 17, further comprising a conductive thin film formed on an upper surface of the second conductive layer,
wherein the cover film is formed so as to cover the second conductive layer and the conductive thin film.

19. A semiconductor device comprising:
a semiconductor substrate having an upper surface and a lower surface;
a first conductive layer formed above the semiconductor substrate; and
a second conductive layer formed on an upper surface of the first conductive layer,
wherein, when viewed from above, the second conductive layer is formed in a region inside an end edge of the first conductive layer, and
wherein the second conductive layer has a plurality of fins extending in one direction in a plane parallel to the upper surface of the first conductive layer.

20. The semiconductor device according to claim 19,
wherein the second conductive layer further includes a plurality of pad portions to which respective bonding wires of a plurality of bonding wires are connected, and
wherein the fin includes a portion extending from the pad portion to one side and another side in the one direction.
